(19) United States
(12) Patent Application Publication
(10) Pub. No.: US 2008/0013134 A1
(43) Pub. Date: Jan. 17, 2008

(54) Image processing device, image processing method, computer readable medium, and computer data signal

(75) Inventors: Yasushi Nishide, Kanagawa (JP); Takanori Okuoka, Kanagawa (JP); Satoshi Yoshikawa, Kanagawa (JP); Seiji Iino, Kanagawa (JP); Ryuichi Ishizuka, Kanagawa (JP); Kazuhiko Miura, Kanagawa (JP)

Correspondence Address: OLIFF & BERRIDGE, PLC, P.O. BOX 320850, ALEXANDRIA, VA, 22320-4850, US

(73) Assignee: FUJI XEROX CO., LTD., Tokyo (JP)

(21) Appl. No.: 11/822,674

(22) Filed: Jul. 9, 2007

(30) Foreign Application Priority Data
Jul. 12, 2006 (JP) 2006-191275

(51) Int. Cl. G03F 3/08

(52) U.S. Cl. 358/518

(57) ABSTRACT

There is provided an image processing device which acquires image data containing a rendering instruction of an object to which color designation has been made, generates a raster image based on the acquired image data, and selectively carries out predetermined color correction on a pixel expressing an object to which color designation according to a predetermined color space has been made, among pixels in the raster image.

### CROSS-REFERENCE TO RELATED APPLICATIONS

This application is based on and claims priority under 35 USC 119 from Japanese Patent Application No. 2006-191275 filed Jul. 12, 2006.

BACKGROUND

1. Technical Field

The present invention relates to an image processing device, an image processing method, a computer readable medium, and a computer data signal.

2. Related Art

In general desktop publishing (DTP) applications, for example, image data containing a rendering instruction of an object is generated. With respect to the object, a color is designated according to a color space, and a rendering color of the object used in printing the image data by a printer and the like is determined based on the color designation. The printer herein may be a commercial printer which is suitable for mass production.

There are cases where, prior to printing the image data generated according to the DTP application as described above by the printer, a user wishes to confirm an output result of an image which is formed on a sheet of paper by an image forming device (such as a desktop printer, and so forth) close at hand. In those cases, for simulation of tones of an image when eventually output by the printer, predetermined color correction may be carried out by the image forming device on hand to the user. By instructing the image forming device to perform image formation based on correction values obtained through the color correction as described above, the image forming device can form an image with a color predicted to be close to the output result of the printer based on original color designation. Accordingly, the user can confirm the output result of the printer with the image forming device on hand, prior to the printing by the printer. The color correction as described above is, for example, executed with respect to pixels included in a raster image after the raster image is generated based on the rendering instruction of the object.

In the image data containing the rendering instruction of the object as described above, color designation according to different color spaces may be carried out on multiple objects included in a single item of image data. Examples of the color space include a CMYK color space composed of four color components of cyan (C), magenta (M), yellow (Y), and black (K), and an RGB color space composed of three color components of red (R), green (G), and blue (B). Here, when the color space used in the raster image generated by an image processing device is the CMYK color space, for example, a color of an object whose color has been designated according to the RGB color space needs to be converted into a color according to the CMYK color space.

### SUMMARY

According to an aspect of the invention, there is provided an image processing device including: an image data acquiring unit that acquires image data containing a rendering instruction of an object to which color designation has been made; a raster image generating unit that generates a raster image based on the acquired image data; and a color correcting unit that selectively carries out predetermined color correction on a pixel expressing an object to which color designation according to a predetermined color space has been made, among pixels in the raster image.

### BRIEF DESCRIPTION OF THE DRAWINGS

An exemplary embodiment of the present invention will be described in detail based on the following figures, wherein:

FIG. 1 is a block diagram showing a schematic structure of an image processing device according to an exemplary embodiment of the present invention;

FIG. 2 is a functional block diagram showing functions of the image processing device according to the exemplary embodiment of the present invention;

FIG. 3 is a flowchart showing an example of processing executed by the image processing device according to the exemplary embodiment of the present invention;

FIG. 4 is an explanatory diagram showing an example of a raster image and position information generated by the image processing device according to the exemplary embodiment of the present invention;

FIG. 5 is a flowchart showing another example of the processing executed by the image processing device according to the exemplary embodiment of the present invention; and

FIG. 6 is an explanatory diagram showing another example of raster images generated by the image processing device according to the exemplary embodiment of the present invention.

### DETAILED DESCRIPTION

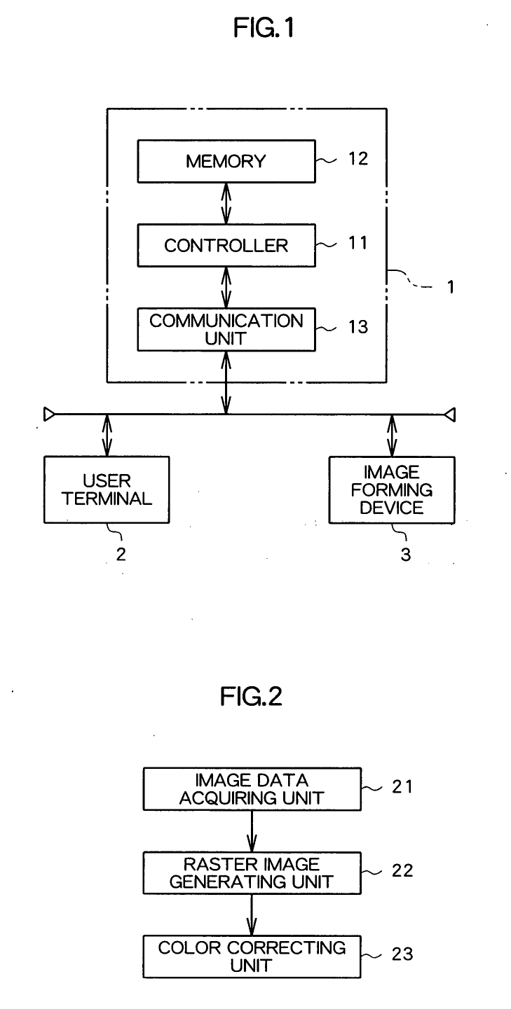

Hereinafter, an exemplary embodiment of the present invention will be described with reference to the drawings. An image processing device 1 according to the exemplary embodiment of the present invention is, for example, a print server, and is composed of a controller 11, a memory 12, and a communication unit 13 as shown in FIG. 1. Here, the image processing device 1 is connected to a user terminal 2 and an image forming device 3 via a communication network.

The controller 11 is, for example, a CPU, and operates according to a program stored in the memory 12. In this exemplary embodiment, the controller 11 generates and outputs raster image data for image formation processing executed by the image forming device 3, based on image data transmitted from the user terminal 2 via the communication network. An example of the processing executed by the controller 11 in this exemplary embodiment will be described later.

The memory 12 is a computer readable information storage medium which holds the program executed by the controller 11. The memory 12 is composed of at least one of a memory element, such as a RAM or a ROM, a disk device, and the like. Further, the memory 12 operates as a work memory of the controller 11.

The communication unit 13 is a network interface and transmits information via the communication network according to an instruction from the controller 11. In addition, the communication unit 13 receives the information transmitted via the communication network and outputs the information to the controller 11.

The user terminal 2 is, for example, a personal computer, which corresponds to information processing device used by the user. In this exemplary embodiment, the user terminal 2 executes a program of a DTP application and generates image data eventually to be a target of printing by a printer (a target printer) based on an operation instruction of the user.

The image forming device 3 forms on paper an image instructed by the image formation instruction transmitted from the image processing device 1. Here, the image forming device 3 forms an image by causing a color material (e.g., toner) of four colors to adhere onto the paper based on designation of respective component values of four color components of cyan (C), magenta (M), yellow (Y), and black (K) included in the image formation instruction.

An image processing system including the image processing device 1 according to this exemplary embodiment is used so that the user having created the image data for printing in the user terminal 2 causes the image forming device 3 to form in advance an image obtained through simulation of a printing result of the target printer (an image forming device as a target of the simulation), for confirmation. In this exemplary embodiment, the image data created in the user terminal 2 is temporarily transmitted to the image processing device 1 according to the operation instruction of the user. Then, the image processing device 1 converts the image data into raster image data that can be processed by the image forming device 3. In this case, the image processing device 1 carries out color correction processing for correcting a rendering color included in the image data so that a tone of the image to be obtained as a result of printing by the target printer is simulated by the image formed on the paper by the image forming device 3. As a result of the color correction processing, a difference in color reproduction properties between the image forming device 3 and the target printer is eliminated, and a color of the image to be obtained when printed by the target printer is simulated by the image forming device 3.

As shown in FIG. 2, the image processing device 1 is composed of, in terms of functions, an image data acquiring unit 21, a raster image generating unit 22, and a color correcting unit 23. Those functions may be realized by the controller 11 executing the program stored in the memory 12. The program may be provided through the communication network such as the Internet, or may be provided while being stored in various computer readable information storage media such as a CD-ROM or a DVD-ROM.

The image data acquiring unit 21 acquires image data to be a formation target of the image forming device 3 by receiving data transmitted from the user terminal 2. The image data in this case contains at least one rendering instruction of an object. The objects are various rendering elements constituting an image to be the formation target, and are units for the color designation by the user.

Here, the color designation of the object includes a color space designation and a designation of component values of respective color components in the color space. Specifically, when a color designation according to the CMYK color space has been made on a certain object, for example, component values are designated for the respective C, M, Y, and K color components. Hereinafter, a color space used for the color designation of the object will be referred to as “user designation color space”. Note that the user designation color space may be different for each object included in the image data.

The raster image generating unit 22 generates raster image based on the image data acquired by the image data acquiring unit 21. Hereinafter, a color space used for the raster image generated by the raster image generating unit 22 will be referred to as “output color space”. In other words, a color of pixels included in the generated raster image is expressed by the component value of respective color components of the output color space. The output color space is a color space used for the image formation processing in the image forming device 3 for image formation. The output color space in this case is the CMYK color space expressed by four color components of C, M, Y, and K. Thus, the image forming device 3 forms an image based on the raster image that has been generated by the raster image generating unit 22 and includes pixels of colors expressed according to the output color space.

Note that in generating the raster image, the raster image generating unit 22 carries out color conversion processing for converting a color designated according to the user designation color space into a color designated according to the output color space, with respect to an object whose user designation color space differs from the output color space among objects included in the image data acquired by the image data acquiring unit 21. In this case, the raster image generating unit 22 converts the color designated according to the user designation color space into a color with which the output result of the target printer is simulated. When a color designation according to the RGB color space is made on a certain object, for example, the raster image generating unit 22 converts the designated color into a color according to the CMYK color space, and generates a raster image according to the CMYK color space by using the converted color.

In addition, the raster image generating unit 22 may generate position information along with the raster image, for realizing selective color correction by the color correcting unit 23 to be described later. Alternatively, the raster image generating unit 22 may generate multiple raster images based on a single item of image data acquired by the image data acquiring unit 21. Descriptions of the processing will be given later.

The color correcting unit 23 selectively carries out predetermined color correction on a pixel expressing an object, to which color designation according to a predetermined color space (correction color space) has been made, among pixels in the raster image generated by the raster image generating unit 22. The correction color space in this case is the output color space which is a color space used for the raster image generated by the raster image generating unit 22.

The color correction in this case refers to processing for determining a corrected component value (correction value) of the respective color components based on the component value of the respective color components of the output color space designated with respect to the pixels in the raster image in such a manner that a color to be formed by the target printer is simulated by the color of the image formed by the image forming device 3. The color correction processing is realized by converting the component value of the color component designated with respect to each pixel into a correction value in accordance with a correction table stored in the memory 12 in advance, for example. Through output of the corrected raster image obtained by the color correction processing to the image forming device 3, the image forming device 3 forms an image obtained through simulation of the output result of the target printer.

Next, examples of processing for realizing the selective color correction by the color correcting unit 23 in association with the raster image generating unit 22 will be described in detail.

First, as a first processing example, a description will be given of a case where the raster image generating unit 22 generates position information along with a raster image, and selective color correction is realized by the color correcting unit 23 using the position information.

In this example, the raster image generating unit 22 generates a raster image and also position information indicating a position of a pixel, which expresses an object to which color designation according to the correction color space has been made, in the raster image. The position information is, for example, data correlating each pixel in the raster image with a value indicating the user designation color space (color space value) of the object expressed by the pixel. In this case, the color space value may be binary data that indicate whether color designation according to the correction color space has been made, or may be a predetermined identification number for identifying multiple kinds of color space. Further, the position information may be data containing the color space value instead of a pixel value in a data format same as that of the image data of each color plate, which indicates the pixel value (component value of the color component) of each pixel for the corresponding color component. In this case, the raster image generating unit 22 may generate the position information as image data of a specific color plate, for example.

Subsequently, with respect to the pixels in the raster image, the color correcting unit 23 judges whether color correction is necessary based on the position information generated by the raster image generating unit 22. For example, when position information containing the color space value described above is generated, the color correcting unit 23 judges whether color correction of each pixel is necessary based on whether the color space value of each pixel contained in the position information matches a predetermined value. Then, color correction is carried out on pixels for which color correction has been judged as necessary, and execution of the color correction is limited for pixels for which color correction has been judged as unnecessary.

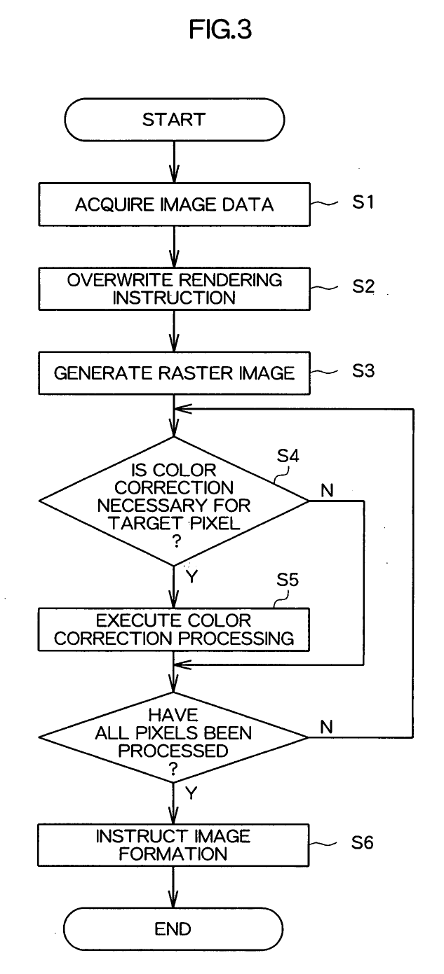

Here, an example of a flow of processing executed by the image processing device 1 in the case of the first processing example will be described with reference to the flowchart of FIG. 3.

First, the image data acquiring unit 21 acquires image data containing a rendering instruction of an object based on data transmitted from the user terminal 2 (S1). Next, the raster image generating unit 22 carries out an overwrite of a rendering instruction for development of position information as image data of a specific color plate with respect to the rendering instruction contained in the acquired image data (S2).

Specifically, for example, when the acquired image data is written in a PostScript language, the raster image generating unit 22 first adds an instruction to carry out an output of the specific color plate. Then, subsequent to the rendering instruction of the object to which color designation according to a color space other than the correction color space has been made, rendering instructions as exemplified below are added, for example.
gsave % save graphic status (set to A)
true setoverprint % set to overprint
[/Separation (TAG)/DeviceGray { }] setcolorspace % set to specific color
1 setcolor % set color space value
0 0 1 1 rectfill % fill in image rendering area
grestore1 % restore graphic status except for coordinate position to original status (restore to A)

In the example described above, a portion from on and after the symbol “%” in each row is a comment portion which indicates a content of processing of each row. Further, “TAG” indicates the image data of the specific color plate representing the position information. Further, the overprint is set for preventing the pixel values set for other color components of C, M, Y, and K from being invalidated due to the setting of the pixel value with respect to the specific color plate. Accordingly, the original color of the image data is expressed by the image data of respective plates of C, M, Y, and K, and information of the color space designated for the object is expressed by the image data of the specific color plate.

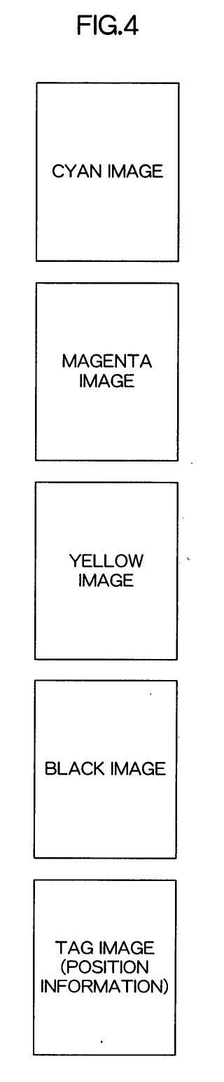

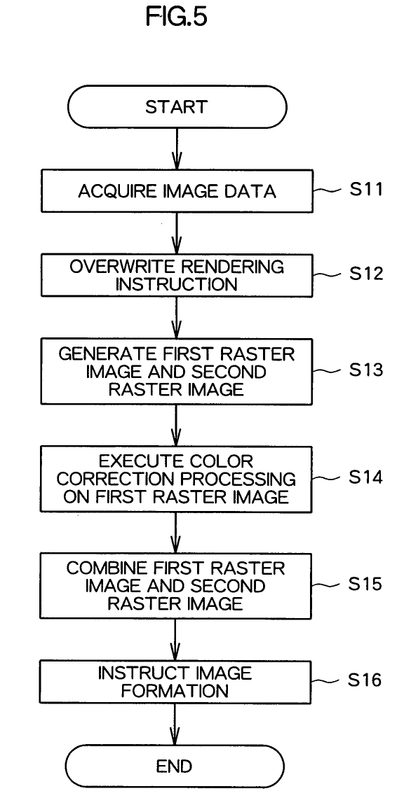

Subsequently, the raster image generating unit 22 generates a raster image based on the image data in which the rendering instruction has been overwritten in S2 (S3). As a result of the processing, as shown in FIG. 4, the raster image generating unit 22 generates image data of respective plates of C, M, Y, and K and image data of a specific color plate expressing position information containing a color space value indicating the color space of each pixel. In the example described above where the rendering instruction is overwritten, the image data of the specific color plate becomes data which has, as the pixel value, a maximum value for the pixels at which the object to which color designation according to the color space other than the correction color space has been made is positioned, and “0” for the pixels other than those described above.

Next, the color correcting unit 23 judges, with respect to a target pixel in the raster image generated in S3, whether color correction is to be carried out based on the pixel value (color space value) of the target pixel included in the image data (position information) of the specific color plate (S4). In the example described above, when the pixel value of the target pixel is “0”, it is judged that the color correction is to be carried out. When the color correction is judged to be carried out, predetermined color correction processing is executed on the target pixel (S5) The color correcting unit 23 repeatedly executes the processes of S4 and S5 on all the pixels in the raster image. Accordingly, selective color correction is executed with respect to the raster image.

After that, the color correcting unit 23 instructs image formation to the image forming device 3 based on the raster image that has been subjected to selective color correction by the processes up to S5 (S6). Thus, the raster image that has been subjected to the color correction is formed on paper by the image forming device 3.

Next, as a second processing example, a case where the raster image generating unit 22 generates multiple raster images and the color correcting unit 23 carries out the color correction on pixels included in the raster image which is a part of the multiple raster images will be described.

In the second processing example, the raster image generating unit 22 generates a first raster image based on the object to which color designation according to the correction color space has been made, among the objects included in the image data acquired by the image data acquiring unit 21, and generates a second raster image different from the first raster image based on the object to which color designation according to the color space other than the correction color space has been made.

In this case, when the object to which the color designation according to the correction color space has been made and the object to which the color designation according to the color space other than the correction color space has been made overlap one another, the raster image generating unit 22 may determine the pixel value of the pixels in the region at which the objects overlap one another (overlapping region) as follows. In other words, the pixel value of the pixels of the overlapping region in the raster image generated based on the object arranged behind the other object is set to “0”. When the user designation color space of the object arranged behind is, for example, the correction color space, the pixel value of the pixels of the overlapping region in the first raster,image is “0”. In contrast, when the user designation color space of the object arranged behind is the color space other than the correction color space, the pixel value of the pixels of the overlapping region in the second raster image is “0”.

Here, the case where the object is arranged behind refers to a case where, when the object is arranged so as to overlap another object, the object is hidden by the another object and becomes invisible in the raster image to be eventually generated. Whether a certain object is to be arranged in front of or behind the other object is determined by, for example, a rendering order of each object. In other words, among the objects that overlap one another, the object that is rendered last is arranged in front of the other objects, whereas the other objects are arranged behind the object. As described above, in either one of the first raster image and the second raster image, by setting the pixel value of the pixels in the overlapping region to “0”, color setting is prevented from being carried out on both the first and second raster images with respect to one pixel.

Subsequently, the color correcting unit 23 carries out the color correction processing on each pixel included in the first raster image that has been generated based on the object to which color designation according to the correction color space has been made. On the other hand, the color correcting unit 23 limits execution of the color correction processing on the second raster image that has been generated based on the object to which color designation according to the color space other than the correction color space has been made. Then, the first raster image that has been subjected to the color correction and the second raster image that has not been subjected to the color correction are combined. In other words, the color correcting unit 23 arranges the first and second raster images so that the images overlap one another, and generates a raster image whose color component of the pixels has been determined based on the pixel value of the pixels included in the two raster images at the same position. Accordingly, a raster image to which selective color correction processing has been executed is obtained.

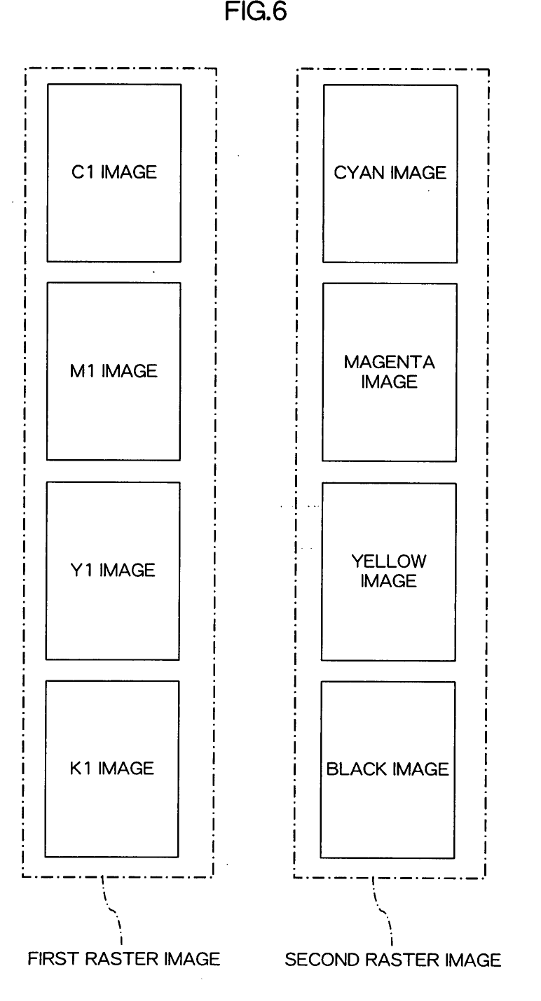

Here, an example of a flow of processing executed by the image processing device 1 in the case of the second processing example will be described with reference to the flowchart of FIG. 5.

As in the case of the first processing example, the image data acquiring unit 21 acquires image data containing a rendering instruction of an object based on data transmitted from the user terminal 2 (S11). Next, the raster image generating unit 22 carries out an overwrite of a rendering instruction for generating first and second raster images with respect to the rendering instruction contained in the acquired image data (S12).

Specifically, for example, when the acquired image data is written in the PostScript language, the raster image generating unit 22 first adds an instruction to carry out an output of a specific color plate as in the first processing example. Note that in this example, the number of specific color plates to be prepared is equal to the number of color components of the output color space (four components of C, M, Y, and K in this case) to be used for generating the first raster image. Further, the raster image generating unit 22 overwrites the rendering instruction as exemplified below. For example, it is assumed that the image data acquired in S11 contains a rendering instruction of an object, to which color designation according to the correction color space has been made, as shown below.
newpath % clear FIG.
0 0 moveto % move to (0, 0)
1 0 lineto % draw straight line from (0, 0) to (1, 0)
1 1 lineto % draw straight line from (1, 0) to (1, 1)
0 1 lineto % draw straight line from (1, 1) to (0, 1)
0 0 0 1 setcmykcolor % designate rendering color (black)
fill % fill in constructed figure

In this case, the raster image generating unit 22 overwrites the rendering instructions as exemplified below.
newpath % clear figure
0 0 moveto % move to (0, 0)
1 0 lineto % draw straight line from (0, 0) to (1, 0)
1 1 lineto % draw straight line from (1, 0) to (1, 1)
0 1 lineto % draw straight line from (1, 1) to (0, 1)
0 0 1 setcmykcolor % designate rendering color (black)
gsave % save graphic status (set to A)
gsave % save graphic status (set to B)
fill % fill in constructed figure
grestore % restore graphic status to original status (restore to B)
true setoverprint % set to overprint
[/DeviceN [(C1) (M1) (Y1) (K1)/DeviceCMYK { }] setcolorspace % set to another CMYK plate (specific color plates)
currentcolor setcolor % set color designated for object
fill % fill in figure in specific color plate
grestore1 % restore graphic status except for coordinate position to original status (restore to A)

In the example described above, a portion from on and after the symbol “%” in each row is a comment portion which indicates a content of processing of each row as in the first processing example. In addition, “C1”, “M1”, “Y1[, and “K1” respectively indicate specific color plates corresponding to the color components of the first raster image. The raster image generating unit 22 generates the first raster image as image data of those specific color plates.

Subsequently, the raster image generating unit 22 generates raster images based on the image data in which the rendering instruction has been overwritten in S12 (S13). As a result of the processing, as shown in FIG. 6, the raster image generating unit 22 generates the first raster image expressed as image data of the four specific color plates and the second raster image expressed as image data of respective C, M, Y, and K plates.

Next, the color correcting unit 23 executes predetermined color correction processing on each pixel of the first raster image among raster images generated in S13 (S14). Then, the color correcting unit 23 combines the first raster image that has been subjected to the color correction in S14 and the second raster image that has been generated in S13 (S15).

After that, the color correcting unit 23 instructs the image forming device 3 to carry out the image formation based on the raster image obtained through combination of S15 (S16). Accordingly, the raster image that has been subjected to the color correction is formed on paper by the image forming device 3.

The foregoing description of the exemplary embodiments of the invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An image processing device, comprising:
an image data acquiring unit that acquires image data containing a rendering instruction of an object to which color designation has been made;
a raster image generating unit that generates a raster image based on the acquired image data; and
a color correcting unit that selectively carries out predetermined color correction on a pixel expressing an object to which color designation according to a predetermined color space has been made, among pixels in the raster image.

2. The image processing device according to claim 1, wherein the predetermined color space comprises a color space used in the raster image generated by the raster image generating unit.

3. The image processing device according to claim 1, further comprising a position information generating unit that generates position information indicating a position of the pixel expressing the object to which the color designation according to the predetermined color space has been made in the raster image,
wherein the color correcting unit selectively carries out the color correction based on the generated position information.

4. The image processing device according to claim 2, further comprising a position information generating unit that generates position information indicating a position of the pixel expressing the object to which the color designation according to the predetermined color space has been made in the raster image,
wherein the color correcting unit selectively carries out the color correction based on the generated position information.

5. The image processing device according to claim 1, wherein:
the raster image generating unit generates a first raster image based on, among objects included in the acquired image data, the object to which the color designation according to the predetermined color space has been made, and generates a second raster image different from the first raster image based on an object to which color designation according to a color space other than the predetermined color space has been made; and
the color correcting unit selectively carries out the color correction by carrying out the color correction on pixels included in the first raster image and by combining the first raster image that has been subjected to the color correction and the second raster image.

6. The image processing device according to claim 2, wherein:
the raster image generating unit generates a first raster image based on, among objects included in the acquired image data, the object to which the color designation according to the predetermined color space has been made, and generates a second raster image different from the first raster image based on an object to which color designation according to a color space other than the predetermined color space has been made; and
the color correcting unit selectively carries out the color correction by carrying out the color correction on pixels included in the first raster image and by combining the first raster image that has been subjected to the color correction and the second raster image.

7. The image processing device according to claim 5, wherein the raster image generating unit generates, when the object to which the color designation according to the predetermined color space has been made and the object to which the color designation according to the color space other than the predetermined color space has been made overlap one another, one of the first raster image and the second raster image so that a pixel value of a pixel in a region where the objects overlap one another in the raster image, which has been generated based on the object arranged behind the other object, is set to “0”.

8. The image processing device according to claim 6, wherein the raster image generating unit generates, when the object to which the color designation according to the predetermined color space has been made and the object to which the color designation according to the color space other than the predetermined color space has been made overlap one another, one of the first raster image and the second raster image so that a pixel value of a pixel in a region where the objects overlap one another in the raster image, which has been generated based on the object arranged behind the other object, is set to “0”.

9. An image processing method, comprising:
acquiring image data containing a rendering instruction of an object to which color designation has been made;
generating a raster image based on the acquired image data; and
selectively carrying out predetermined color correction on a pixel expressing an object to which color designation according to a predetermined color space has been made, among pixels in the raster image.

10. A computer readable medium storing a program causing a computer to execute a process comprising:
acquiring image data containing a rendering instruction of an object to which color designation has been made;
generating a raster image based on the acquired image data; and
selectively carrying out predetermined color correction on a pixel expressing an object to which color designation according to a predetermined color space has been made, among pixels in the raster image.

11. A computer data signal embodied in a carrier wave for enabling a computer to perform a process comprising:
acquiring image data containing a rendering instruction of an object to which color designation has been made;
generating a raster image based on the acquired image data; and
selectively carrying out predetermined color correction on a pixel expressing an object to which color designation according to a predetermined color space has been made, among pixels in the raster image.
